(19) United States
(12) Patent Application Publication
(10) Pub. No.: US 2025/0096137 A1
(43) Pub. Date: Mar. 20, 2025

(54) SEMICONDUCTOR DEVICE

(71) Applicant: Sumitomo Electric Industries, Ltd., Osaka-shi, Osaka (JP)

(72) Inventor: Taizo TATSUMI, Osaka-shi (JP)

(73) Assignee: Sumitomo Electric Industries, Ltd., Osaka-shi, Osaka (JP)

(21) Appl. No.: 18/727,484

(22) PCT Filed: Dec. 26, 2022
(86) PCT No.: PCT/JP2022/047995

§ 371 Date: Jul. 9, 2024

(30) Foreign Application Priority Data
Jan. 13, 2022 (JP) 2022-003471

(51) Int. Cl. H01L 23/528; H01L 27/088; H01L 29/40; H01L 29/78

(52) U.S. Cl. CPC H01L 23/5286; H10D 30/60; H10D 64/111; H10D 84/83

(57) ABSTRACT

A semiconductor device includes a substrate, a source electrode extending, a drain electrode, a first gate electrode extending in a first direction and provided between the source electrode and the drain electrode, a second gate electrode extending in the first direction and provided on the substrate in the first direction of the first gate electrode between the source electrode and the drain electrode, a gate pad provided so as to interpose the first gate electrode between the second gate electrode and the gate pad and electrically connected to the first gate electrode, a gate wiring provided above the source electrode and electrically connecting the gate pad and the second gate electrode, and a guard metal layer provided between the gate wiring and the drain electrode, at least a part of the guard metal layer being provided above the source electrode and electrically connected to the source electrode.

### TECHNICAL FIELD

The present disclosure relates to a semiconductor device. This application is based upon and claims the benefit of priority of Japanese Patent Application No. 2022-003741, filed on Jan. 13, 2022, the entire contents of which are incorporated herein by reference.

### BACKGROUND ART

In a field effect transistor (FET) having a finger-shaped source electrode, a finger-shaped gate electrode, and a finger-shaped drain electrode, it is known that a plurality of unit FETs each having the source electrode, the gate electrode, and the drain electrode are arranged in an extending direction of the electrodes (for example, PTLs 1 and 2).

### CITATION LIST

### Patent Literature

PTL 1: Japanese Laid-open Patent Publication No. 2002-299351

PTL 2: U.S. Patent Application Publication No. 2017/0271329

PTL 2: Japanese Laid-open Patent Publication No. 2012-23212

### SUMMARY OF INVENTION

A semiconductor device according to an aspect of the present disclosure includes: a substrate; a source electrode that extends in a first direction and is provided on the substrate; a drain electrode that extends in the first direction and is provided on the substrate; a first gate electrode that extends in the first direction and is provided on the substrate between the source electrode and the drain electrode; a second gate electrode that extends in the first direction and is provided on the substrate in the first direction of the first gate electrode between the source electrode and the drain electrode; a gate pad that is provided so as to interpose the first gate electrode between the second gate electrode and the gate pad, and electrically connected to the first gate electrode; a gate wiring that is provided above the source electrode on a side opposite to the substrate, extends in the first direction, and electrically connects the gate pad and the second gate electrode; and a guard metal layer that is provided between the gate wiring and the drain electrode, extends in the first direction, at least a part of the guard metal layer being provided above the source electrode and electrically connected to the source electrode.

### BRIEF DESCRIPTION OF DRAWINGS

FIG. 1 is a block diagram of an amplifier in which a FET of a first embodiment is used.

FIG. 2 is a plan view of the FET according to the first embodiment.

FIG. 3 is a cross-sectional view taken along a line A-A in FIG. 2.

FIG. 4 is a cross-sectional view taken along a line B-B in FIG. 2.

FIG. 5 is a cross-sectional view taken along a line C-C in FIG. 2.

FIG. 6 is a plan view of a semiconductor device according to a first comparative example.

FIG. 7 is a cross-sectional view of the semiconductor device according to the first comparative example.

FIG. 8 is a cross-sectional view of a semiconductor device according to a first modification of the first embodiment.

FIG. 9 is a plan view of a semiconductor device according to a second embodiment.

FIG. 10 is an enlarged plan view of a vicinity between gate electrodes 14a and 14b in FIG. 9.

FIG. 11 is a cross-sectional view taken along a line A-A in FIG. 10.

FIG. 12 is a cross-sectional view taken along a line B-B in FIG. 10.

FIG. 13 is an enlarged plan view of a vicinity between the gate electrodes 14a and 14b of a semiconductor device according to a first modification of the second embodiment.

FIG. 14 is a cross-sectional view taken along a line A-A in FIG. 13.

FIG. 15 is a cross-sectional view taken along a line B-B in FIG. 13.

FIG. 16 is a cross-sectional view taken along a line C-C in FIG. 13.

FIG. 17 is a plan view of a semiconductor device according to a third embodiment.

FIG. 18 is a plan view of a semiconductor device according to a first modification of the third embodiment.

FIG. 19 is a cross-sectional view taken along a line A-A in FIG. 18.

FIG. 20 is a plan view of a semiconductor device according to a second modification of the third embodiment.

FIG. 21 is a cross-sectional view of a semiconductor device according to a fourth embodiment.

FIG. 22 is a plan view of a semiconductor device according to a fifth embodiment.

FIG. 23 is an enlarged plan view of a vicinity between the gate electrodes 14a and 14b in FIG. 22.

FIG. 24 is a plan view of a semiconductor device according to a first modification of the fifth embodiment.

FIG. 25 is an enlarged plan view of a vicinity between gate electrodes 14a and 14c in FIG. 24.

FIG. 26 is an enlarged plan view of a vicinity between gate electrodes 14c and 14b in FIG. 24.

### DESCRIPTION OF EMBODIMENTS

### Technical to be Solved by Present Disclosure

In the PTLs 1 and 2, the width of the gate electrode of the unit FET can be shortened by arranging a plurality of unit FETs in an extending direction of the electrodes. Therefore, the gate resistance can be suppressed. However, a gate wiring that electrically connects the gate pad and the gate electrode away from the gate pad is provided above the unit FET. This increases a parasitic capacitance between the gate wiring and the drain electrode, and deteriorates the characteristics such as a gain.

The present disclosure has been made in view of the above problems, and an object thereof is to suppress deterioration of the characteristics.

### Effect of Present Disclosure

According to the present disclosure, it is possible to suppress deterioration of the characteristics.

### Details of Embodiments of Present Disclosure

First, embodiments of the present disclosure will be listed and described. (1) An aspect of the present disclosure is a semiconductor device including: a substrate; a source electrode that extends in a first direction and is provided on the substrate; a drain electrode that extends in the first direction and is provided on the substrate; a first gate electrode that extends in the first direction and is provided on the substrate between the source electrode and the drain electrode; a second gate electrode that extends in the first direction and is provided on the substrate in the first direction of the first gate electrode between the source electrode and the drain electrode; a gate pad that is provided so as to interpose the first gate electrode between the second gate electrode and the gate pad, and electrically connected to the first gate electrode; a gate wiring that is provided above the source electrode on a side opposite to the substrate, extends in the first direction, and electrically connects the gate pad and the second gate electrode; and a guard metal layer that is provided between the gate wiring and the drain electrode, extends in the first direction, at least a part of the guard metal layer being provided above the source electrode and electrically connected to the source electrode. By providing the guard metal layer, the deterioration of the characteristics can be suppressed.

(2) In the above (1), an end of the guard metal layer close to the drain electrode in a second direction perpendicular to the first direction may be located closer to the gate wiring than an end of the first gate electrode close to the source electrode in the second direction.

(3) In the above (1) or (2), the semiconductor device further may include an insulating film provided between the source electrode, and the gate wiring and the guard metal layer in a normal direction of an upper surface of the substrate.

(4) In any of the above (1) to (3), the semiconductor device further may include a gate connection wiring that is provided above the source electrode on a side opposite to the substrate, and extends in a second direction orthogonal to the first direction, a first end of the gate connection wiring being connected to the gate wiring, and a second end of the gate connection wiring on a side opposite to the first end being electrically connected to an end of the second gate electrode close to the first gate electrode outside the source electrode.

(5) In any of the above (1) to (3), the semiconductor device further may include: a gate connection wiring that is provided on the substrate, extends in a second direction perpendicular to the first direction, and electrically connects the gate wiring and the second gate electrode; wherein the gate connection wiring intersects the source electrode between the substrate and the source electrode in a non-contact manner, and the source electrode has an opening in a region intersecting the gate connection wiring when viewed from a normal direction of an upper surface of the substrate, and the gate connection wiring intersects the source electrode in a non-contact manner below the source electrode and is electrically connected to the gate wiring through the opening.

(6) In any of the above (1) to (3), the semiconductor device further may include: a gate connection wiring that is provided on the substrate, extends in a second direction perpendicular to the first direction, and electrically connects the gate wiring and the second gate electrode; wherein the source electrode is separated on the substrate into a first source electrode and a second source electrode, the first source electrode and the drain electrode interpose the first gate electrode, and the second source electrode and the drain electrode interpose the second gate electrode, the guard metal layer electrically connects the first source electrode and the second source electrode, and the gate connecting wiring intersects the guard metal layer in a non-contact manner below the guard metal layer.

(7) In the above (5) or (6), an end of the guard metal layer on a side opposite to the gate pad may be located at a position coincident with an end of the gate wiring on the side opposite to the gate pad or at a position farther away from the end of the gate wiring on the side opposite to the gate pad toward the side opposite to the gate pad.

(8) In any of the above (1) to (7), the first gate electrode and the second gate electrode may be separated from each other in the first direction on an upper surface of the substrate.

(9) In any one of the above (1) to (8), in a normal direction of an upper surface of the substrate, a thickness of each of the source electrode and the drain electrode may be larger than a thickness of each of the first gate electrode and the second gate electrode.

(10) In any one of the above (1) to (9), the semiconductor device further may include: a third gate electrode that extends in the first direction between the source electrode and the drain electrode and is provided on the substrate between the first gate electrode and the second gate electrode; wherein the gate wiring electrically connects the gate pad and the third gate electrode.

(11) In any of the above (1) to (10), a plurality of source electrodes, a plurality of drain electrodes, a plurality of first gate electrodes, a plurality of second gate electrodes, a plurality of gate wirings, and a plurality of guard metal layers may be provided in a direction in which the source electrodes and the drain electrodes are arranged. The semiconductor device may include a connection wiring that electrically connects adjacent guard metal layers provided with one of the drain electrodes interposed therebetween and intersects the drain electrodes in a non-contact manner above the drain electrodes.

(12) In any of the above (1) to (11), the semiconductor device further may include a drain pad provided on the substrate. The source electrode may include a first source electrode and a second source electrode, the first source electrode and the drain electrode may interpose the first gate electrode, and the second source electrode and the drain electrode may interpose the second gate electrode. The drain electrode may include a first drain electrode and a second drain electrode, the first drain electrode and the second source electrode may interpose the first gate electrode, and the second drain electrode and the second source electrode may interpose the second gate electrode. The drain pad may be provided so as to interpose the second drain electrode between the drain pad and the first drain electrode, and be electrically connected to the second drain electrode. A length of the first source electrode in a second direction orthogonal to the first direction may be larger than a length of the second source electrode in the second direction. A length of the first drain electrode in the second direction may be smaller than a length of the second drain electrode in the second direction.

(13) In any of the above (1) to (11), the semiconductor device further may include: a third gate electrode that extends in the first direction between the source electrode and the drain electrode and is provided on the substrate between the first gate electrode and the second gate electrode; and a drain pad provided on the substrate. The gate wiring electrically may connect the gate pad and the third gate electrode. The source electrode may include a first source electrode, a second source electrode and a third source electrode, the first source electrode and the drain electrode may interpose the first gate electrode, the second source electrode and the drain electrode may interpose the second gate electrode, and the third source electrode and the drain electrode interpose the third gate electrode. The drain electrode may include a first drain electrode, a second drain electrode, and a third drain electrode, the first drain electrode and the first source electrode may interpose the first gate electrode, the second drain electrode and the second source electrode may interpose the second gate electrode, and the third drain electrode and the third source electrode may interpose the third gate electrode. The drain pad may be provided so as to interpose the second drain electrode between the third drain electrode and the drain pad, and be electrically connected to the second drain electrode. A length of the third source electrode in a second direction orthogonal to the first direction may be smaller than a length of the first source electrode in the second direction and larger than a length of the second source electrode in the second direction. A length of the third drain electrode in the second direction may be larger than a length of the first drain electrode in the second direction and smaller than a length of the second drain electrode in the second direction.

(14) In the above (13), the gate wiring may include a first gate wiring that is provided above the first source electrode and electrically connects the gate pad and the third gate electrode, and a second gate wiring that is provided on the third source electrode and electrically connects the gate pad and the second gate electrode. A length of the first gate wiring in the second direction may be larger than a length of the second gate wiring in the second direction.

Specific examples of a semiconductor device according to an embodiment of the present disclosure will be described below with reference to the drawings. It should be noted that the present disclosure is not limited to these examples, and is defined by claims, and is intended to embrace all the variations within the meaning and range of equivalency of the claims.

### First Embodiment

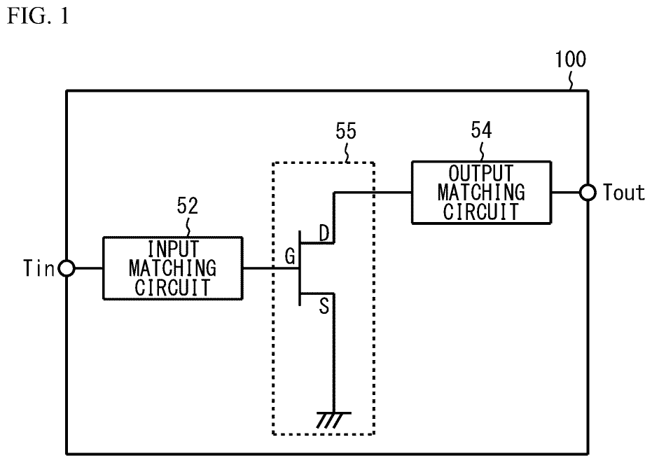

FIG. 1 is a block diagram of an amplifier in which a FET according to the first embodiment is used. As illustrated in FIG. 1, an amplifier 100 includes a FET 55, an input matching circuit 52, and an output matching circuit 54. A source S of the FET 55 is connected to ground. A high frequency signal input from an input terminal Tin is input to a gate G of the FET 55 via the input matching circuit 52. The high frequency signal amplified by the FET 55 is output from an output terminal Tout via the output matching circuit 54. The input matching circuit 52 matches an input impedance of the input terminal Tin with an impedance when the input matching circuit 52 is seen from the gate G of the FET 55 so that those impedances are complex conjugate. The output matching circuit 54 matches an output impedance of the output terminal Tout with an impedance when the output matching circuit 54 is seen from a drain D of the FET 55 so that those impedances are complex conjugate. The amplifier 100 is a power amplifier for wireless communication, for example, for 0.5 GHz to 10 GHz (for example, 3.5 GHz). The output power of the amplifier 100 is, for example, 30 dBm to 56 dBm.

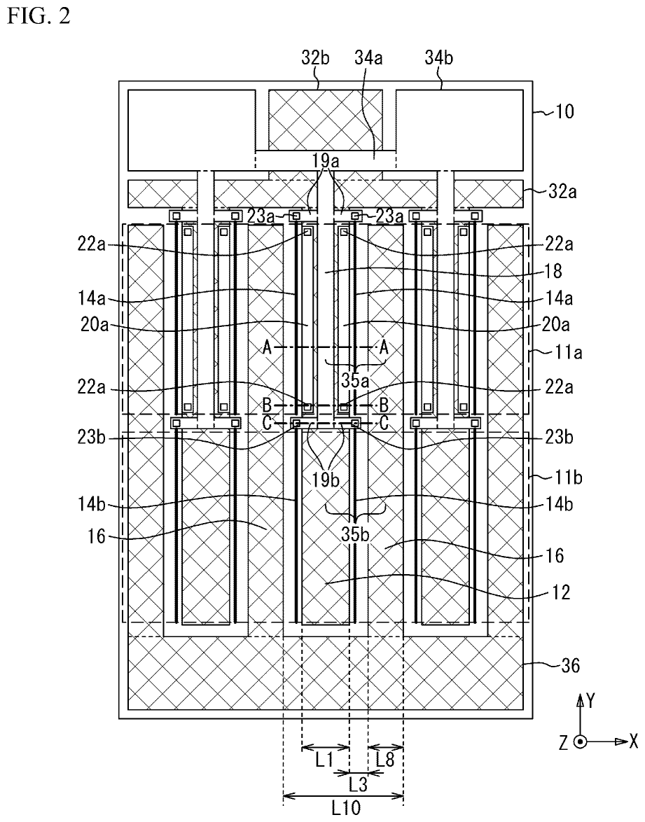

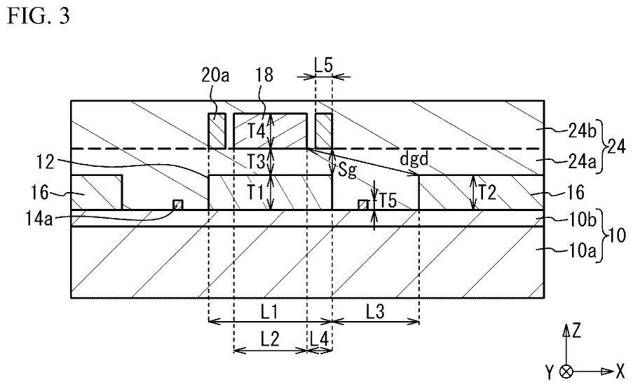

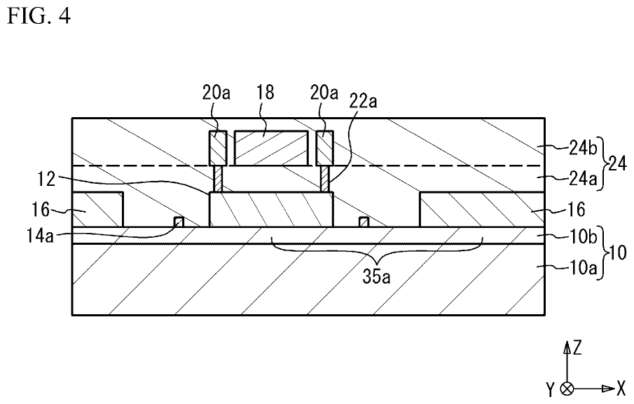

FIG. 2 is a plan view of the FET according to the first embodiment. FIGS. 3 to 5 are cross-sectional views taken along lines A-A, B-B and C-C in FIG. 2, respectively. A normal direction of an upper surface of a substrate 10 is defined as a Z direction, an extending direction of each of finger-shaped electrodes is defined as a Y direction (first direction), and an arrangement direction of each of the electrodes is defined as an X direction (second direction).

As illustrated in FIGS. 2 to 5, the substrate 10 includes a substrate 10a and a semiconductor layer 10b provided on the substrate 10a. In an XY plane parallel to the X direction and the Y direction, a region of the semiconductor layer 10b inactivated by ion implantation or the like is an inactive region 13, and regions not inactivated are active regions 11a and 11b. Source electrodes 12, gate electrodes 14a and 14b, drain electrodes 16, gate wirings 18, 19a and 19b, a guard metal layer 20a, a source bus bar 32a, a source pad 32b, a gate wiring 34a, a gate pad 34b and a drain pad 36 are provided on the substrate 10. The plurality of source electrodes 12, the plurality of drain electrodes 16, the plurality of gate electrodes 14a and 14b, the plurality of gate wirings 18, and the plurality of guard metal layers 20a are provided in the X direction.

The active regions 11a and 11b are arranged in the Y direction and extend in the X direction. The active region 11a is provided with a plurality of unit FETs 35a arranged in the X direction, and the active region 11b is provided with a plurality of unit FETs 35b arranged in the X direction. The plurality of source electrodes 12 extend in the Y direction across the active regions 11a and 11b. The plurality of source electrodes 12 are connected in common to the source bus bar 32a at +Y side ends of the source electrodes 12. The source bus bar 32a is connected to the source pad 32b. The plurality of drain electrodes 16 extend in the Y direction across the active regions 11a and 11b. The plurality of drain electrodes 16 are connected in common to the drain pad 36 at −Y side ends of the drain electrodes 16. The plurality of source electrodes 12 and the plurality of drain electrodes 16 are provided alternately. Between one source electrode 12 and one drain electrode 16, the gate electrodes 14a and 14b are provided on the active regions 11a and 11b, respectively. The gate electrode 14b is provided on the negative (−) side of the gate electrode 14a in the Y direction. The source electrode 12, the gate electrode 14a and the drain electrode 16 form the unit FET 35a, and the source electrode 12, the gate electrode 14b and the drain electrode 16 form the unit FET 35b.

An insulating film 24a is formed on the substrate 10 so as to cover the source electrode 12, the drain electrode 16, and the gate electrodes 14a and 14b. The gate wirings 18, 19a and 19b and the guard metal layer 20a are provided on the insulating film 24a. The gate wirings 18, 19a and 19b and the guard metal layer 20a are formed in the same manufacturing process, for example, and are metal layers made of the same material, and have substantially the same thicknesses. An insulating film 24b is provided on the insulating film 24a so as to cover the gate wirings 18, 19a and 19b and the guard metal layer 20a. The insulating films 24a and 24b form an insulating film 24. Via wirings 22a, 23a and 23b penetrate the insulating film 24a and extend in the Z direction.

Pads 15a are provided at the ends of the gate electrodes 14a and 14b in the plus (+) direction of the Y direction outside the active regions 11a and 11b. The pads 15a is a metal layer made of the same material as the gate electrode 14a. The gate electrode 14a is electrically connected to the gate wiring 19a through the pads 15a and the via wirings 23a. The gate electrode 14b is electrically connected to the gate wiring 19b through the pads 15a and the via wirings 23b at the + direction end in the Y direction. The first ends of the gate wirings 19a and 19b are connected to the gate wiring 18. The gate wiring 18 is provided so as to overlap with the source electrode 12 when viewed from the Z direction, and extends in the Y direction. The plurality of gate wirings 18 are connected to the gate wiring 34a or the gate pad 34b at the ends of the gate wirings 18 in the + direction of the Y direction. The gate wiring 34a connects the plurality of gate pads 34b with each other and intersects the source pad 32b in a non-contact manner.

The guard metal layer 20a is provided between the gate wiring 18 and the drain electrode 16 in the active region 11a. In the first embodiment, the guard metal layer 20a is provided so as to overlap with the source electrode 12 when viewed from the Z direction. Both ends of the guard metal layer 20a are electrically connected to the source electrode 12 through the via wirings 22a, and have substantially the same potential as the source electrode 12.

A source potential (for example, a reference potential such as a ground potential) is supplied to the source electrode 12 from the source pad 32b and the source bus bar 32a. A gate potential (for example, a high frequency signal and a gate bias voltage) is supplied from the gate pad 34b and the gate wiring 34a to the gate electrode 14a through the gate wirings 18 and 19a. The gate potential is supplied from the gate pad 34b and the gate wiring 34a to the gate electrode 14b through the gate wirings 18 and 19b. A drain bias voltage is supplied from the drain pad 36 to each drain electrode 16. The high frequency signal amplified in each of the units FETs 35a and 35b is output from the drain electrode 16 to the drain pad 36.

In the unit FET 35a, the high frequency signal is input from the end of the gate electrode 14a in the + direction of the Y direction. In the unit FET 35b, the high frequency signal is input from the end of the gate electrode 14b in the + direction of the Y direction. When the high frequency signals are input to the gate electrode 14a from both ends of the gate electrode 14a in the + direction and the − direction of the Y direction, the high frequency characteristics of the unit FET 35a deteriorate due to a phase difference or the like. In the first embodiment, since the end of the gate electrode 14a in the − direction of the Y direction and the end of the gate electrode 14b in the + direction of the Y direction are not connected to each other, the deterioration of the high frequency characteristics of the unit FET 35a can be suppressed.

When the semiconductor device is a nitride semiconductor device, the substrate 10a is, for example, a SiC substrate, a silicon substrate, a GaN substrate, or a sapphire substrate. The semiconductor layer 10b includes a nitride semiconductor layer such as a GaN layer, an AlGaN layer and/or an InGaN layer. When the semiconductor device is, for example, a GaAs semiconductor device, the substrate 10a is, for example, a GaAs substrate. The semiconductor layer 10b includes an arsenide semiconductor layer such as a GaAs layer, an AlGaAs layer and/or an InGaAs layer. The source electrode 12 and the drain electrode 16 are metal films, and are, for example, a titanium film and an aluminum film, for example, from the substrate 10 side. A gold film may be provided on the aluminum film. The gate electrodes 14a and 14b and the pad 15a are metal films, for example, a nickel film and a gold film. The gate wirings 18, 19a, 19b and the guard metal layer 20a are, for example, a gold layer, a copper layer or an aluminum layer. The via wirings 22a, 23a and 23b are metal layers, for example, a gold layer, a copper layers, a tungsten layer or an aluminum layer. The insulating film 24 is an organic insulating film made of, for example, polyimide resin or BCB (Benzocyclobutane). The insulating film 24 may be an inorganic insulating film such as a silicon nitride film or a silicon oxide film.

Referring to FIG. 3, a length L1 of the source electrode 12 in the X direction is, for example, 5 μm to 50 μm. A length L2 of the gate wiring 18 in the X direction is, for example, 3 μm to 45 μm. A distance L3 between the source electrode 12 and the drain electrode 16 in the X direction is, for example, 3 μm to 20 μm. A distance L4 between the end of the gate wiring 18 and the end of the source electrode 12 in the X direction is 1 μm to 10 μm. A thickness T1 of the source electrode 12 and a thickness T2 of the drain electrode 16 are, for example, 1 μm to 6 μm. A thickness T5 of the gate electrodes 14a and 14b is, for example, 1 μm or less, and is smaller than the thicknesses T1 and T2. A thickness T3 of the insulating film 24a between the source electrode 12 and the gate wiring 18 is, for example, 0.5 μm to 10 μm. A thickness T4 of the gate wirings 18, 19a and 19b and the guard metal layer 20a is, for example, 0.5 μm to 6 μm.

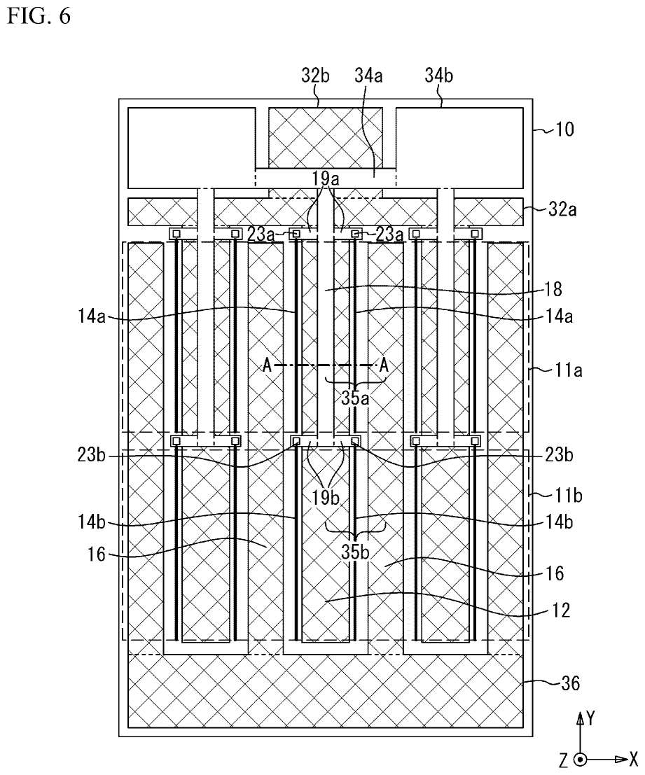

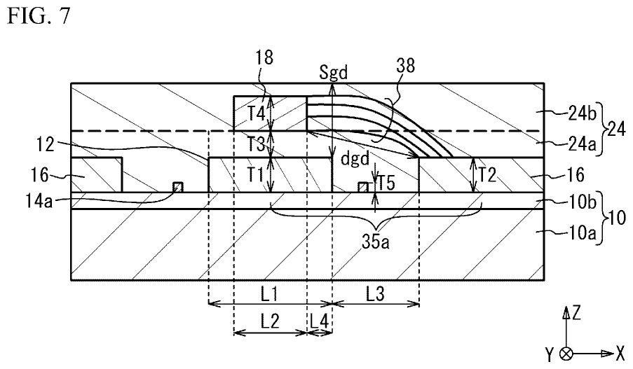

FIG. 6 is a plan view of a semiconductor device according to a first comparative example. FIG. 7 is a cross-sectional view of the semiconductor device according to the first comparative example. As illustrated in FIGS. 6 and 7, the guard metal layer 20a and the via wiring 22a are not provided. The configurations of the first comparative example are the same as those of the first embodiment, and the description thereof will be omitted.

As illustrated in FIG. 7, in the first comparative example, the lines of electric force 38 are extended between the gate wiring 18 and the drain electrode 16, and the gate wiring 18 and the drain electrode 16 are electrically coupled to each other. A distance between the gate wiring 18 and the drain electrode 16 is denoted by dgd, and an area through which the lines of electric force 38 pass is denoted by Sgd. At this time, a parasitic capacitance Cp_gd between the gate wiring 18 and the drain electrode 16 caused by the lines of electric force 38 is expressed by a following equation 1.

$$Cp\_gd = {ε}_{0} - {ε}_{r} ( Sgd ) / ( dgd ) \qquad Equation 1$$

Where the ε₀ is a vacuum dielectric constant, and the εᵣ is a relative dielectric constant of the insulating film 24. The εᵣ is, for example, 2.4 to 10.

A maximum oscillation frequency fmax of the FET is expressed by a following equation 2.

$$f max \sim √ ( ft / ( 8 π Rg Cgd ) ) \qquad Equation 2$$

Where the ft is a cutoff frequency, the Rg is a gate resistance, and the Cgd is a gate-drain capacitance. As the Cp_gd increases, the Cgd increases and the fmax decreases.

As an example, when the Cp_gd is calculated by using electromagnetic field analysis with L3+L4=20 μm, T1=T2=4 μm, T3 =6 μm, T4 =4 μm, and εᵣ=3.5, the Cp_gd is about 0.7 fF with respect to a gate width of 100 μ min the Y direction. In a GaN HEMT (Gallium Nitride High Electron Mobility Transistor) used for an amplifier of 1 GHz to 10 GHz, the Cgd (not considering Cp_gd) is, for example, 1 fF to 5 fF per 100 μm of gate width. Therefore, the Cgd increases by 14% to 70% by the Cp_gd. From the equation 2, the fmax is reduced by 6% to 23%.

In order to reduce the parasitic capacitance Cp_gd, it is conceivable to reduce the relative dielectric constant εᵣ of the insulating film 24. However, if the εᵣ is made smaller, a function of the insulating film 24 as a protective film is lowered, and a moisture resistance, a dust resistance, or the like is lowered. It is also conceivable to increase the distance L3+L4 corresponding to the distance between the gate wiring 18 and the drain electrode 16. When the length L2 of the gate wiring 18 is reduced, the gate resistance increases. Therefore, in order to increase the distance L3+L4, it is conceivable to increase the length L1 of the source electrode 12. However, the area of the FET is increased, and the semiconductor device is increased in size.

As illustrated in FIG. 3, in the first embodiment, the guard metal layer 20a short-circuited to the source electrode 12 is provided on the side of the gate wiring 18. The length L5 of the guard metal layer 20a in the X direction is, for example, 0.5 μm to 3 μm. As a result, the area Sg through which the lines of electric force connecting the gate wiring 18 and the drain electrode 16 passes is the region between the source electrode 12 and the guard metal layer 20a. When L5=2 μm is satisfied as an example, the other dimensions and the like are the same as those in the calculation of the first comparative example, and the Cp_gd is calculated by using the electromagnetic field analysis, the Cp_gd with respect to the gate width of 100 μm is about 0.2 fF. As described above, in the first embodiment, the Cp_gd can be reduced to ⅓ or less as compared with the first comparative example. This makes it possible to increase the fmax as compared with the first comparative example.

According to the first embodiment, the gate electrode 14a (first gate electrode) is provided on the substrate 10 between the source electrode 12 and the drain electrode 16. The gate electrode 14b (second gate electrode) is provided on the substrate 10 in the − direction of the Y direction of the gate electrode 14a between the source electrode 12 and the drain electrode 16. The gate pad 34b is provided so as to interpose the gate electrode 14a between the gate pad 34b and the gate electrode 14b, and is electrically connected to the gate electrode 14a. The gate wiring 18 is provided above the source electrode 12 and electrically connects the gate pad 34b and the gate electrode 14b. The guard metal layer 20a is provided between the gate wiring 18 and the drain electrode 16, is provided above the source electrode 12, and is electrically connected to the source electrode 12. This can reduce the Cp_gd, and thus improve the characteristics of the FET. In addition, since the length L1 need not be increased, the semiconductor device can be suppressed from being increased in size.

### First Modification of First Embodiment

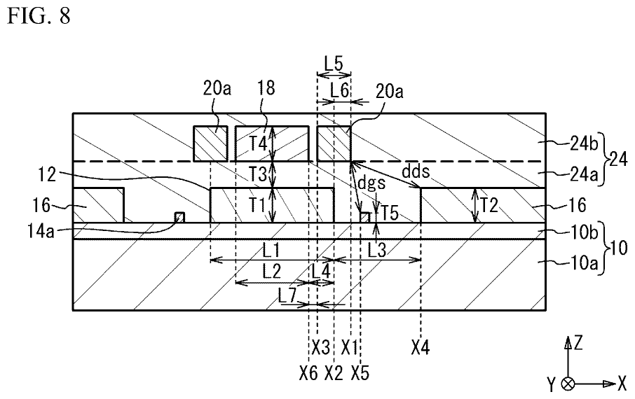

FIG. 8 is a cross-sectional view of a semiconductor device according to a first modification of the first embodiment. FIG. 8 illustrates a modification of a cross section corresponding to the position of FIG. 3 of the first embodiment. As illustrated in FIG. 8, an end X1 of the guard metal layer 20a close to the drain electrode 16 may be located closer to the drain electrode 16 than an end X2 of the source electrode 12 close to the drain electrode 16. An end X3 of the guard metal layer 20a close to the gate wiring 18 may be located closer to the drain electrode 16 than an end X6 of the gate wiring 18 close to the drain electrode 16. However, if the end X3 is too close to the gate wiring 18, the parasitic capacitance Cp_gs increases. From this viewpoint, a distance L7 between the end X3 of the guard metal layer 20a close to the gate wiring 18 and the end X6 of the gate wiring 18 close to the drain electrode 16 is preferably equal to or more than ⅓ of the distance L4, and more preferably equal to or more than ½ of the distance L4. If the distance L7 is too large, the overlap between the end X3 of the guard metal layer 20a and the end X2 of the source electrode 12 becomes small, and it becomes difficult to electrically connect the guard metal layer 20a to the source electrode 12 via the via wiring 22a. From this viewpoint, the distance L7 is preferably smaller than the distance L4, and more preferably equal to or smaller than ⅔ of the distance L4.

For example, when the distance L7 between the end X3 and the end X6 is increased, and the end X1 is located closer to the drain electrode 16 than the end X2, the gate electrode 14a and the guard metal layer 20a are likely to be coupled to each other by the electric field as illustrated by the coupling distance dgs. This increases the parasitic capacitance Cp_gs between the gate and the source. Further, as illustrated by the coupling distance dds, the drain electrode 16 and the guard metal layer 20a are likely to be coupled to each other by the electric field. This increases the parasitic capacitance Cp_ds between the drain and the source. A distance L6 between the end X1 and the end X2 in the X direction is, for example, 0 μm to 5 μm. When the distance L6 is set to 0 μm to 5 μm, the dimensions other than the L6 are set to the same numerical values as those in the calculation of the Cp_gd in FIG. 3, and the Cp_gs is calculated by using the electromagnetic field analysis, the Cp_gs is about 0.1 fF to 0.5 fF per 100 μm of the gate width. In the GaN HEMT, the Cgs without considering the Cp_gs is, for example, about 20 fF to 200 fF per 100 μm of the gate width, and the Cp_gs is sufficiently smaller than the Cgs.

The end X1 of the guard metal layer 20a close to the drain electrode 16 may be located closer to the source electrode 12 than the end X4 of the drain electrode 16 close to the source electrode 12. However, if the end X1 is too close to the drain electrode 16, the parasitic capacitances Cp_gs and Cp_ds increase. From this viewpoint, the end X1 of the guard metal layer 20a close to the drain electrode 16 is preferably coincident with an end X5 of the gate electrode 14a close to the source electrode 12 or is located closer to the gate wiring 18 than the end X5, is more preferably coincident with a midpoint between the ends X2 and X5 or is located closer to the source electrode 12 than the midpoint between the ends X2 and X5, and is still more preferably coincident with the end X2 of the source electrode 12 close to the drain electrode 16 or is located closer to the gate wiring 18 than the end X2.

The insulating film 24a is provided between the source electrode 12, and the gate wiring 18 and the guard metal layer 20a. This makes it possible to improve the moisture resistance, the dust resistance, and the like of the unit FET 35a. Since the dielectric constant of the insulating film 24a is higher than that of the air, the Cp_gd between the gate wiring 18 and the drain electrode 16 is increased. Therefore, it is preferable to provide the guard metal layer 20a.

The via wiring 22a penetrates the insulating film 24a and electrically connects the source electrode 12 and the guard metal layer 20a. This allows the guard metal layer 20a to have the same potential as the source electrode 12. In addition, the guard metal layer 20a can be electrically connected to the source electrode 12 without increasing the size of the semiconductor device.

The gate wiring 19b (gate connection wiring) is provided above the source electrode 12 and extends in the X direction, and a first end thereof is electrically connected to the gate wiring 18, and the other second end thereof is electrically connected to the end of the gate electrode 14b close to the gate electrode 14a outside the source electrode 12 through the via wiring 23b and the pad 15a. Thereby, the gate wiring 18 and the gate electrode 14b can be electrically connected between the gate electrodes 14a and 14b.

The gate electrodes 14a and 14b are separated from each other on the upper surface of the substrate 10. This makes it possible to suppress interference between the gate electrodes 14a and 14b and improve the high frequency characteristics. The gate electrodes 14a and 14b may be connected to each other on the upper surface of the substrate 10.

The source electrode 12 and the drain electrode 16 are thicker than the gate electrodes 14a and 14b. In this case, the parasitic capacitance due to the electric field coupling between the gate electrode 14a and the drain electrode 16 is small, and the parasitic capacitance Cp_gd due to the electric field coupling between the gate wiring 18 and the drain electrode 16 in the first comparative example becomes a problem. Therefore, it is preferable to provide the guard metal layer 20a.

### Second Embodiment

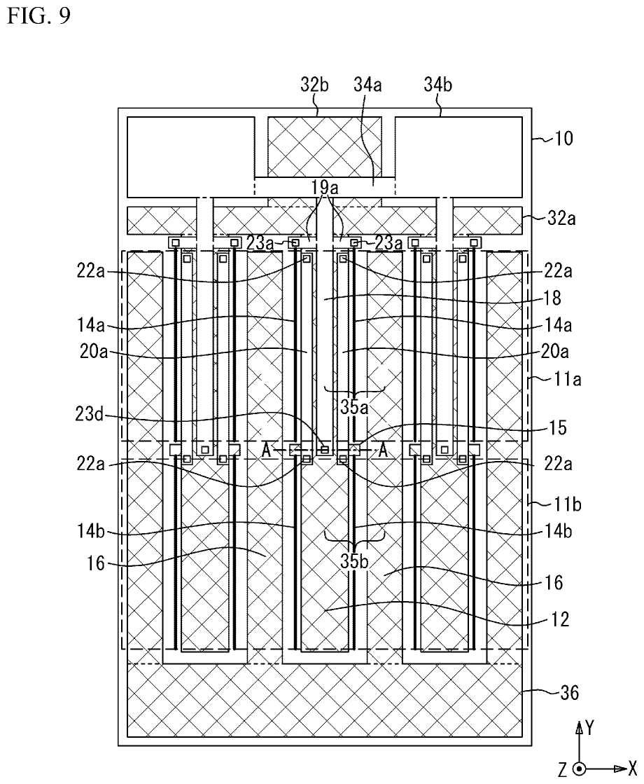

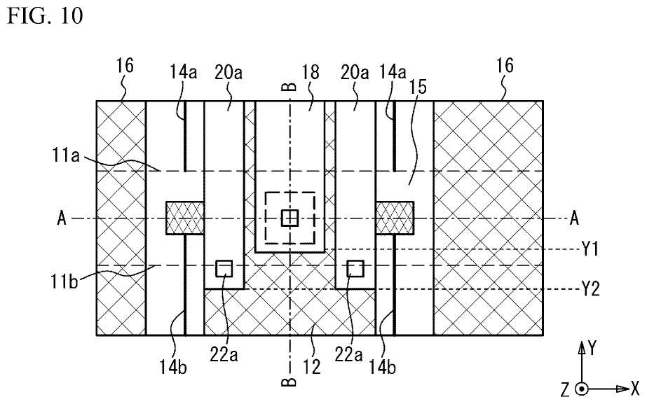

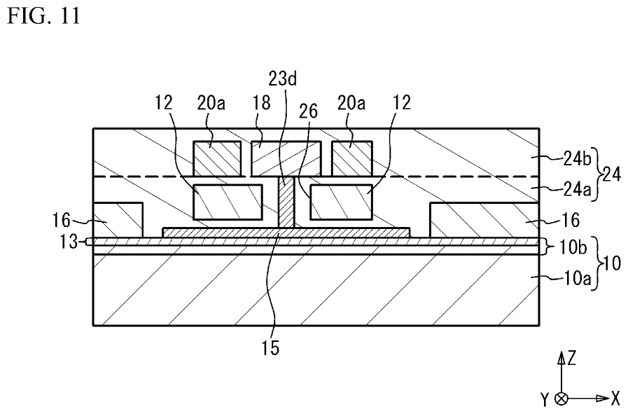

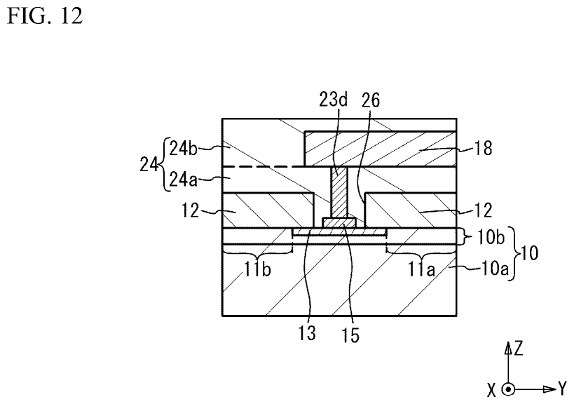

FIG. 9 is a plan view of a semiconductor device according to a second embodiment. FIG. 10 is an enlarged plan view of a vicinity between the gate electrodes 14a and 14b in FIG. 9. FIG. 11 is a cross-sectional view taken along a line A-A in FIG. 10. FIG. 12 is a cross-sectional view taken along a line B-B in FIG. 10.

As illustrated in FIGS. 9 to 12, the source electrode 12 is provided between the gate electrodes 14a and 14b in the Y direction (that is, in an inactive region between the active regions 11a and 11b), and is separated from the substrate 10 in the Z direction. A gate connection wiring 15 is provided in contact with the substrate 10 between the gate electrodes 14a and 14b in the Y direction. The gate connection wiring 15 extends in the X direction and intersects the source electrode 12 in a non-contact manner. The gate connection wiring 15 is, for example, a metal film formed by the same manufacturing process as that of the gate electrodes 14a and 14b and made of the same material as that of the gate electrodes 14a and 14b. The source electrode 12 is provided with an opening 26 so as to overlap with the gate wiring 18 in plan view. A via wiring 23d is provided through the insulating film 24a in the opening 26. The via wiring 23d electrically connects and short-circuits the gate wiring 18 and the gate connection wiring 15. The other configurations are the same as those of the first embodiment, and the description thereof is omitted.

According to the second embodiment, the gate connecting wiring 15 is provided on the substrate 10 in contact therewith, and electrically connects the gate wiring 18 and the gate electrode 14b via the via wiring 23d. The source electrode 12 is separated from the substrate 10 in the Z direction between the gate electrodes 14a and 14b when viewed from the direction in which the source electrode 12 and the drain electrode 16 are arranged (i.e., the X direction), and the source electrode 12 has the opening 26 in a part of a region where the gate wiring 18 overlaps with the gate connection wiring 15 when viewed from the Z direction. The gate connection wiring 15 extends in the X direction, intersects the source electrode 12 extending in the Y direction in a non-contact manner between the substrate 10 and the source electrode 12 in the Z direction, and is electrically connected to the gate wiring 18 through the opening 26. Thus, the gate wiring 18 and the gate electrode 14b can be electrically connected between the gate electrodes 14a and 14b.

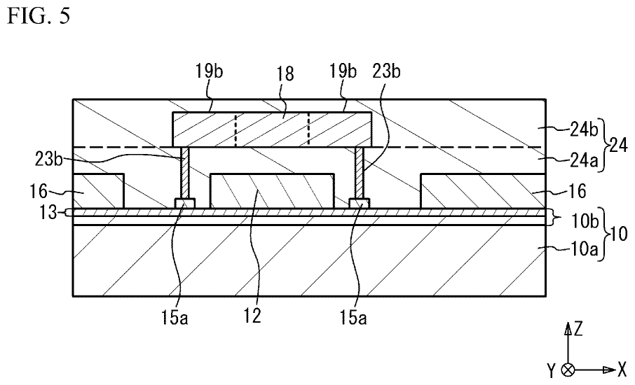

In the first embodiment, as illustrated in FIG. 5, the gate wiring 19b and the drain electrode 16 are close to each other between the gate electrodes 14a and 14b. This increases the electric field coupling between the gate wiring 19b and the drain electrode 16, and increases the parasitic capacitance Cp_gd. According to the second embodiment, as illustrated in FIGS. 9 to 11, an end Y2 of the guard metal layer 20a in the − direction of the Y direction (an end opposite to the gate pad 34b) is located further in the − direction of the Y direction (the end opposite to the gate pad 34b) than an end Y1 of the gate wiring 18 in the − direction of the Y direction (the end opposite to the gate pad 34b). Thereby, the guard metal layer 20a suppresses the electric field coupling between the gate wiring 18 and the drain electrode 16. Therefore, the parasitic capacitance Cp_gd can be suppressed.

In the cross section illustrated in FIG. 11, when an XZ cross-sectional area of the source electrode 12 is reduced by the opening 26, the current that can flow through the source electrode 12 is reduced. This is because the upper limit of the current density that can be supplied to the source electrode 12 is determined in accordance with the cross-sectional area of the source electrode 12. According to the second embodiment, the guard metal layer 20a is electrically connected to the source electrode 12 by the via wirings 22a at positions closer to the − direction side in the Y direction than the opening 26. Thereby, a reduced amount of the upper limit of the current that can flow through the source electrode 12 due to the opening 26 can be compensated by the current flowing through the guard metal layer 20a.

The substrate 10 includes the active regions 11a (first active regions) and 11b (second active regions) in which the semiconductor layer 10b is activated, and an inactive region in which the semiconductor layer 10b is deactivated between the active regions 11a and 11b. The gate connection wiring 15 is provided on the inactive region. This can suppress the parasitic capacitance caused by the gate connection wiring.

### First Modification of Second Embodiment

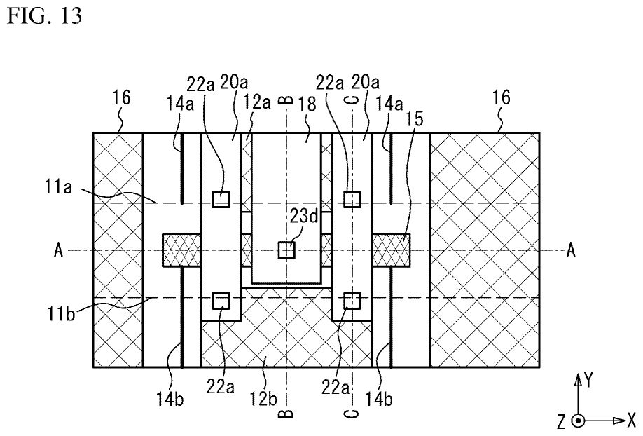

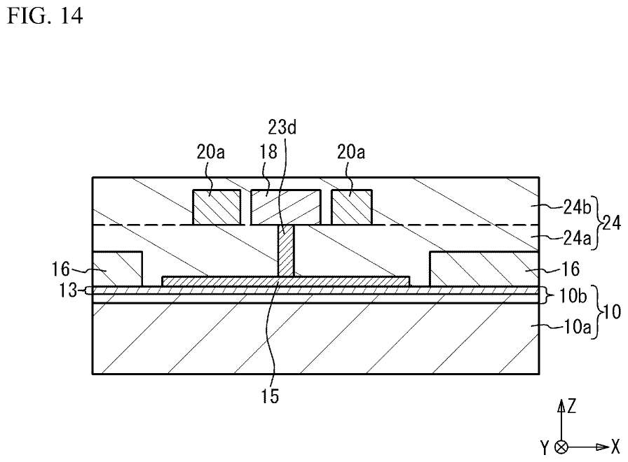

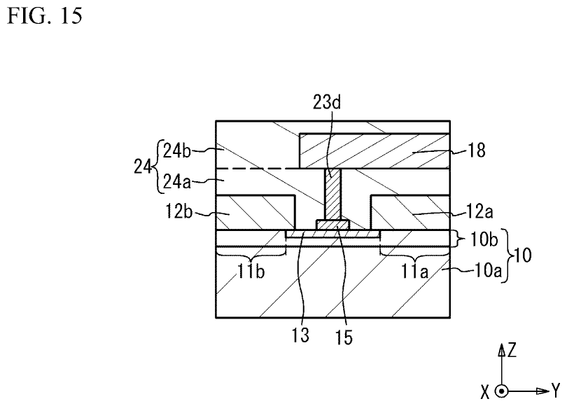

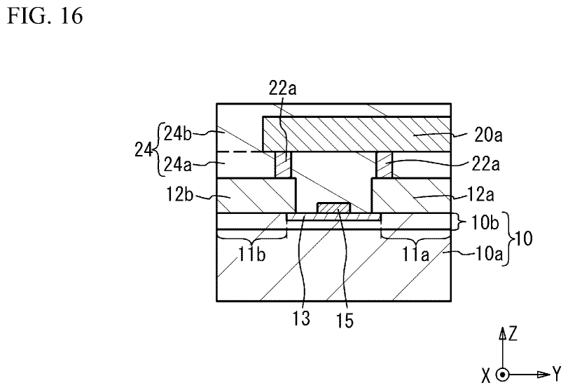

FIG. 13 is an enlarged plan view of a region between the gate electrodes 14a and 14b of the semiconductor device according to the first modification of the second embodiment. FIG. 14 is a cross-sectional view taken along a line A-A in FIG. 13. FIG. 15 is a cross-sectional view taken along a line B-B in FIG. 13. FIG. 16 is a cross-sectional view taken along a line C-C in FIG. 13.

As illustrated in FIGS. 13 to 16, a source electrode 12a is provided on the active region 11a, and the gate electrode 14a is interposed between the source electrode 12a and the drain electrode 16. The source electrode 12b is provided on the active region 11b, and the gate electrode 14b is interposed between the source electrode 12b and the drain electrode 16. The source electrodes 12a and 12b are separated in the Y direction on the inactive region 13. The guard metal layer 20a extends in the −Y direction beyond the end of the source electrode 12a in the + direction of the Y direction, and the end of the guard metal layer 20a in the −Y direction is located above the end of the source electrode 12b in the +direction of the Y direction in the Z direction. At the end of the source electrode 12a in the − direction of the Y direction, the via wirings 22a electrically connect the guard metal layer 20a and the source electrode 12a. At the end of the source electrode 12b in the + direction of the Y direction, the via wirings 22a electrically connect the guard metal layer 20a and the source electrode 12b. As a result, the source electrodes 12a and 12b are electrically connected to each other through the guard metal layer 20a and the via wirings 22a.

The gate connection wiring 15 is provided on the substrate 10 so as to extend in the X direction between the source electrodes 12a and 12b in the Y direction. The gate connection wiring 15 and the guard metal layer 20a intersect each other in a non-contact manner in the Z direction. The via wiring 23d electrically connects the gate connection wiring 15 and the gate wiring 18. The other configurations are the same as those of the second embodiment, and the description thereof is omitted.

According to the first modification of the second embodiment, the source electrodes 12a and 12b are separated in the Y direction on the substrate 10, and the guard metal layer 20a electrically connects the source electrodes 12a and 12b via the via wirings 22a. The gate connection wiring 15 intersects the guard metal layer 20a in a non-contact manner below the substrate 10 side in the Z direction of the guard metal layer 20a. Thus, the gate wiring 18 and the gate electrode 14b can be electrically connected between the gate electrodes 14a and 14b. In addition, the source electrodes 12a and 12b can be electrically connected to each other. In the first modification of the second embodiment, the guard metal layer 20a suppresses the electric field coupling between the gate wiring 18 and the drain electrode 16 between the gate electrodes 14a and 14b, as in the second embodiment. Therefore, the parasitic capacitance Cp_gd can be suppressed.

### Third Embodiment

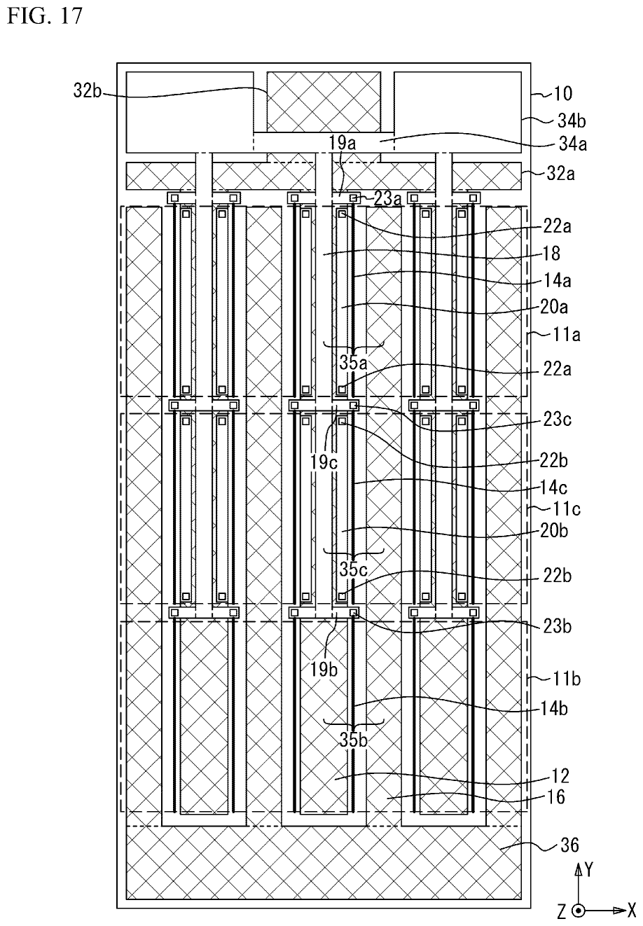

FIG. 17 is a plan view of a semiconductor device according to a third embodiment. In the third embodiment, as compared with the first embodiment, an active region 11c is provided between the active regions 11a and 11b as illustrated in FIG. 17. In the active region 11c, the gate electrode 14c is provided between the source electrode 12 and the drain electrode 16. The source electrode 12, the gate electrode 14c and the drain electrode 16 form a unit FET 35c. Between the gate electrodes 14a and 14c, the gate wiring 19c electrically connects the end of the gate electrode 14c in the +direction of the Y direction and the gate wiring 18 through via wirings 23c. In the active region 11c, a guard metal layer 20b is provided above the source electrode 12 on a side opposite to the substrate 10 in the Z direction. The guard metal layer 20b extends in the Y direction, and both ends thereof are electrically connected and short-circuited to the source electrode 12 through the via wirings 22b. The other configurations are the same as those of the first embodiment, and the description thereof is omitted.

According to the third embodiment, the gate electrode 14c (third gate electrode) extends in the Y direction and is provided on the substrate 10 between the gate electrodes 14a and 14b between the source electrode 12 and the drain electrode 16. The gate wiring 18 electrically connects the gate pad 34b and the gate electrode 14c via the via wirings 23c. Thereby, three unit FETs 35a to 35c can be provided in the Y direction. This can further reduce the gate resistance. Four or more unit FETs may be provided in the Y direction.

### First Modification of Third Embodiment

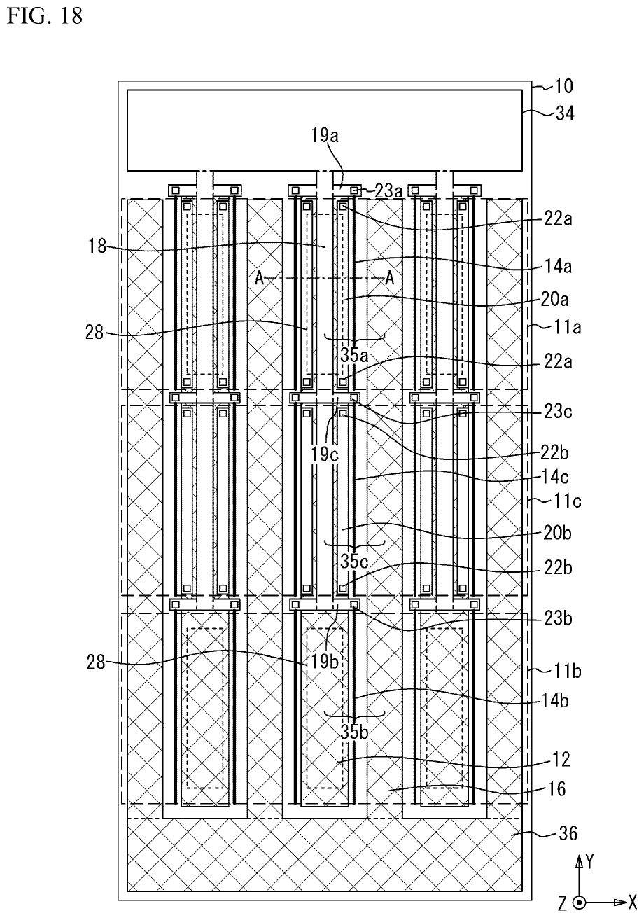

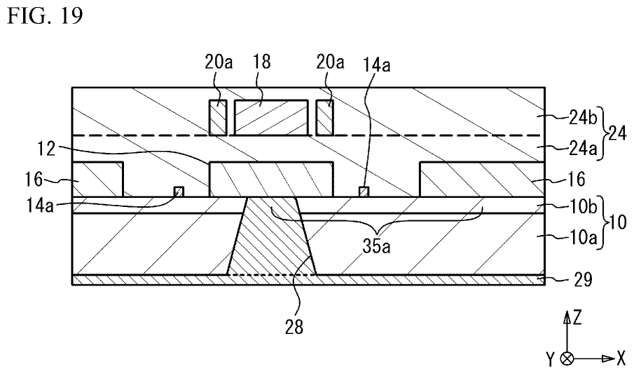

FIG. 18 is a plan view of a semiconductor device according to a first modification of the third embodiment, and FIG. 19 is a cross-sectional view taken along a line A-A in FIG. 18. In FIG. 18, vias 28 are illustrated by thick broken lines. As illustrated in FIG. 18, the source electrode 12 may be provided with the via 28 penetrating the substrate 10. A metal layer 29 is provided on the lower surface of the substrate 10, and the metal layer 29 is electrically connected to and short-circuited to the source electrode 12 through the via 28. A reference potential (e.g., a ground potential) is supplied to the metal layer 29. Thereby, the reference potential is supplied to the source electrode 12. The other configurations are the same as those of the third embodiment, and the description thereof is omitted.

In the first modification of the third embodiment, the source inductance can be reduced by providing the vias 28. The source pad 32b and the source bus bar 32a as illustrated in FIG. 17 of the third embodiment may not be provided. This can reduce a layout area. In the first modification of the third embodiment, the vias 28 are provided in the unit FETs 35a and 35b, but the via 28 may be provided in at least one of the unit FETs 35a to 35c. The vias 28 may be provided in the semiconductor devices of the first and second embodiments and the modification thereof.

### Second Modification of Third Embodiment

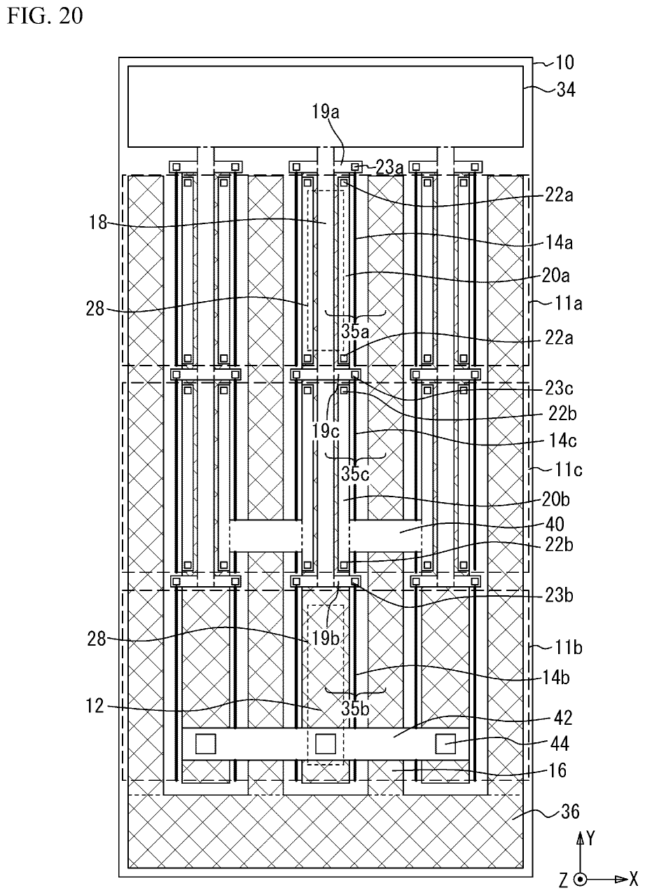

FIG. 20 is a plan view of a semiconductor device according to a second modification of the third embodiment. As illustrated in FIG. 20, the vias 28 are provided in some of the source electrodes 12 arranged in the X direction. A connection wiring 40 extends in the X direction above the drain electrode 16, intersects the drain electrode 16 extending in the Y direction in a non-contact manner, and electrically connects the guard metal layers 20b adjacent to each other in the X direction. The connection wiring 40 is formed integrally with the guard metal layer 20b. A connection wiring 42 extends in the X direction above the drain electrode 16, intersects the drain electrode 16 extending in the Y direction in a non-contact manner, and electrically connects the source electrodes 12 adjacent to each other in the X direction. The source electrode 12 and the connection wiring 42 are electrically connected and short-circuited via the via wirings 44 penetrating the insulating film 24a. The other configuration is the same as that of the first modification of the third embodiment, and the description thereof is omitted.

If the vias 28 are provided in all the source electrodes 12, the rigidity of the substrate 10 is lowered, and the substrate 10 is easily damaged. According to the second modification of the third embodiment, the vias 28 are formed in some of the plurality of source electrodes 12. This can suppress a decrease in rigidity of the substrate 10. The source electrode 12 provided with the via 28 and the source electrode 12 not provided with the via 28 are electrically connected via the connection wiring 40 and/or 42. This can suppress a source inductance.

In particular, the connection wiring 40 electrically connects the adjacent guard metal layers 20b provided with the drain electrode 16 interposed therebetween, and intersect the drain electrode 16 in a non-contact manner above the drain electrode 16. This can further reduce the source inductance. The connection wiring 40 and/or 42 may electrically connect the source electrode 12 provided with the via 28 and the source electrode 12 not provided with the via 28, electrically connect the source electrodes 12 provided with the via 28 to each other, or electrically connect the source electrodes 12 not provided with the via 28 to each other. In either case, the source inductance can be reduced.

### Fourth Embodiment

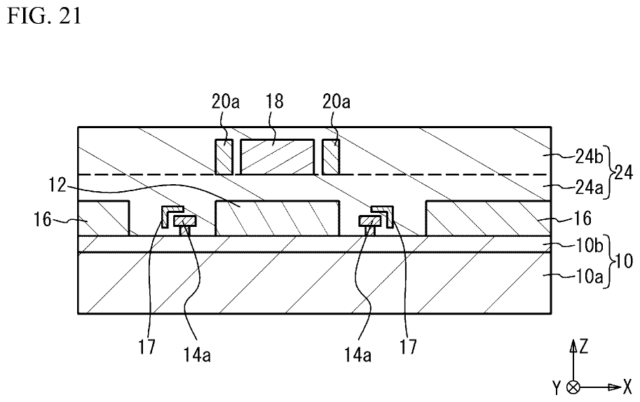

FIG. 21 is a cross-sectional view of a semiconductor device according to a fourth embodiment. As illustrated in FIG. 21, the gate electrodes 14a are T-shaped gates. Source walls 17 are provided above the substrate 10 between the gate electrodes 14a and the drain electrodes 16. The source walls 17 are electrically connected to the source electrode 12 and supplied with a reference potential. Parts of the source walls 17 may be provided above the gate electrode 14a. The other configurations are the same as those of the first embodiment, and the description thereof is omitted.

The source wall 17 is provided to suppress gate parasitic capacitance between the gate electrode 14a and the drain electrode 16. Since the gate electrode 14a is thinner than the source electrode 12 and the drain electrode 16, the upper surface of the source wall 17 is lower than the upper surfaces of the source electrode 12 and the drain electrode 16. Therefore, even if the source wall 17 is provided, it is difficult to suppress the parasitic capacitance Cp_gd between the gate wiring 18 and the drain electrode 16. Therefore, it is preferable to provide the guard metal layer 20a. In the first to third embodiments and the modification thereof, the source walls may be provided in the gate electrodes 14a to 14c as in the fourth embodiment. In the first to third embodiments and the modified embodiments thereof, the cross-sectional shape of the gate electrodes 14a to 14c may be T-shaped as in the fourth embodiment.

### Fifth Embodiment

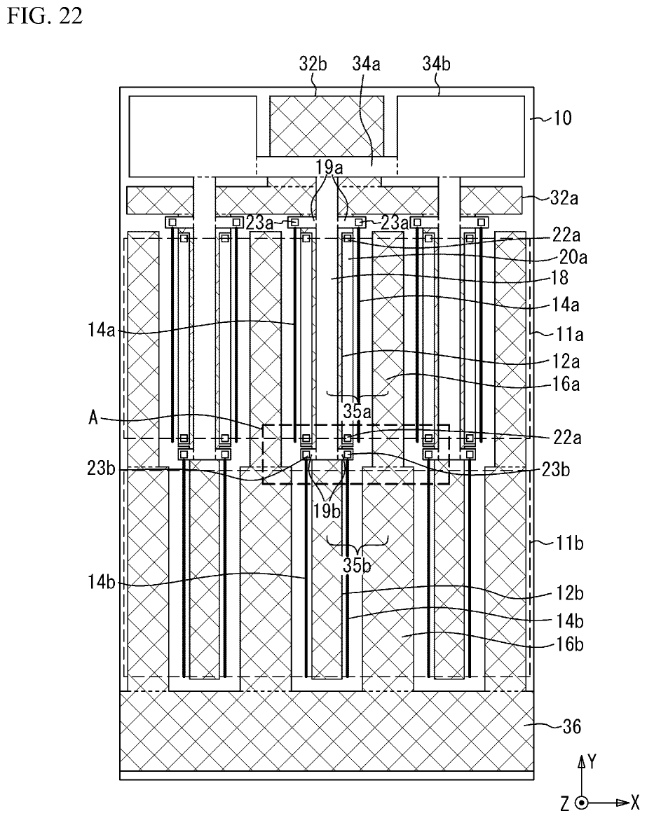

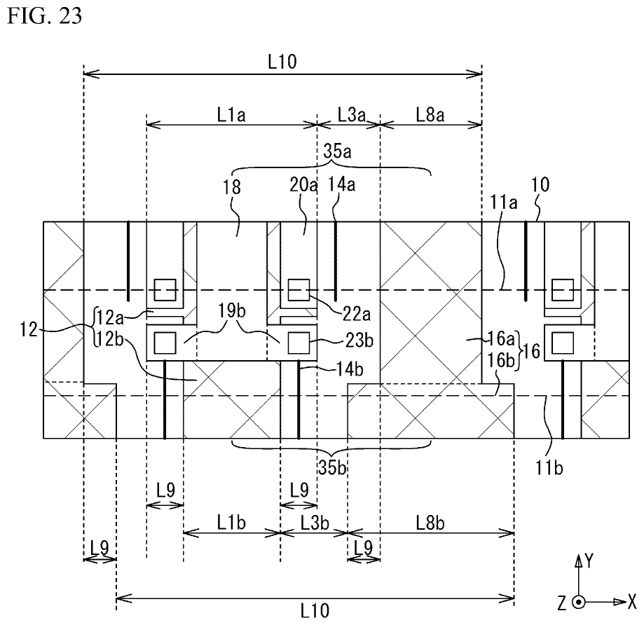

FIG. 22 is a plan view of a semiconductor device according to a fifth embodiment. FIG. 23 is an enlarged plan view of a vicinity between the gate electrodes 14a and 14b in FIG. 22.

As illustrated in FIGS. 22 and 23, the source electrode 12 includes the source electrodes 12a and 12b, and the drain electrode 16 includes drain electrodes 16a and 16b. The source electrode 12a and the drain electrode 16a interpose the gate electrode 14a to form the unit FET 35a. The source electrode 12b and the drain electrode 16b interpose the gate electrode 14b to form the unit FET 35b.

Lengths of the source electrodes 12a and 12b in the X direction are L1a and L1b, respectively. Lengths of the drain electrodes 16a and 16b in the X direction are L8a and L8b, respectively. A distance between the source electrode 12a and the drain electrode 16a in the X direction is L3a, and a distance between the source electrode 12b and the drain electrode 16b in the X direction is L3b. The distances L3a and L3b are substantially equal. The other configurations are the same as those of the first embodiment, and the description thereof is omitted.

In the first embodiment, as illustrated in FIG. 2, the lengths L1 of the source electrode 12 in the X direction in the unit FETs 35a and 35b are the same as each other, the lengths L8 of the drain electrode 16 in the X direction in the unit FETs 35a and 35b are the same as each other, and the distances L3 between the source electrode 12 and the drain electrode 16 in the X direction in the unit FETs 35a and 35b are the same as each other. In the first embodiment, the length L10 in the X direction of two unit FETs 35a (and 35b) is given by:

$$L 10 = L 1 + 2 \times L 3 + L 8$$

In the first embodiment, a current Isa flowing through the source electrode 12 of the unit FET 35a is larger than a current Isb flowing through the source electrode 12 of the unit FET 35b. On the other hand, a current Idb flowing through the drain electrode 16 of the unit FET 35b is larger than a current Ida flowing through the drain electrode 16 of the unit FET 35a. The length L1 of the source electrode 12 is determined so that the current Isa flowing through the source electrode 12 of the unit FET 35a does not exceed the maximum current density of the source electrode 12. The length L8 of the drain electrode 16 is determined so that the current Idb flowing through the drain electrode 16 of the unit FET 35b does not exceed the maximum current density of the drain electrode 16. The maximum current density is a maximum current density allowed to flow through the source electrode 12 and the drain electrode 16 in terms of design.

In the first embodiment, the source pad 32b is electrically connected to the source electrode 12 of the unit FET 35a, and a current is supplied to the source electrode 12 of the unit FET 35b through the source electrode 12 of the unit FET 35a. The drain pad 36 is electrically connected to the drain electrode 16 of the unit FET 35b, and a current is supplied to the drain electrode 16 of the unit FET 35a through the drain electrode 16 of the unit FET 35b. Therefore, the current Isb flowing through the source electrode 12 of the unit FET 35b is smaller than the maximum current density, and the current Ida flowing through the drain electrode 16 of the unit FET 35a is smaller than the maximum current density. For example, if the gate widths in the Y direction of the unit FETs 35a and 35b are assumed to be substantially the same, the current Isb is approximately ½ of the current Isa, and the current Ida is approximately ½ of the current Idb.

According to the fifth embodiment, the length L1a of the source electrode 12a (first source electrode) in the X direction is larger than the length L1b of the source electrode 12b (second source electrode) in the X direction. The length L8a of the drain electrode 16a (first drain electrode) in the X direction is smaller than the length L8b of the drain electrode 16b (second drain electrode) in the X direction. For example, a difference between the length L1a of the source electrode 12a and the length L1b of the source electrode 12b is 2×L9, and a difference between the length L8a of the drain electrode 16a and the length L8b of the drain electrode 16b is 2×L9. At this time, the length L10 in the X direction of two unit FETs 35a (and 35b) is given by:

$$L 10 = L 1 a + 2 \times L 3 a + L 8 a = L 1 b + 2 \times L 3 b + L 8 b$$

$$and$$

$$L 10 = L 1 a + 2 \times L 3 a + L 8 b * 2 \times L 9$$

The length L1a of the source electrode 12a in the X direction and the length L8b of the drain electrode 16b in the X direction are determined by the maximum current density, and therefore are the same as the lengths L1 and L8 in the first embodiment, respectively. Therefore, in the fifth embodiment, the length L10 can be shortened by 2×L9 as compared with the first embodiment. This makes it possible to reduce the chip size of the semiconductor device and to miniaturize the semiconductor device.

A preferred range of L9 is discussed. Assuming that the gate widths in the Y direction of the unit FETs 35a and 35b are substantially the same, the current Isb is approximately ½ of the current Isa. Therefore, when the length L1b is set to ½ of the length L1a, the current Isb becomes approximately the maximum current density. Similarly, since the current Ida is about ½ of the current Idb, the current Ida becomes substantially the maximum current density when the length L8a is set to ½ of the length L8b. From the viewpoint that the currents Isb and Ida do not exceed the maximum current density, the following relationship is established.

$$\begin{matrix}L 1 b > 1 / 2 \times L 1 a \\ i . e . L 9 < 1 / 4 \times L 1 a\end{matrix}$$

$$and$$

$$\begin{matrix}L 8 a > 1 / 2 \times L 8 b \\ i . e . L 9 < 1 / 4 \times L 8 b\end{matrix}$$

Thus, the length L1b is preferably 0.5 times or more, and more preferably 0.6 times or more the length L1a. The length L8a is preferably 0.5 times or more, and more preferably 0.6 times or more the length L8b.

From the viewpoint of miniaturization of the semiconductor device, the length L1b is preferably 0.9 times or less, more preferably 0.8 times or less, and still more preferably 0.7 times or less the length L1a. The length L8a is preferably 0.9 times or less, more preferably 0.8 times or less, and still more preferably 0.7 times or less the length L8b.

### First Modification of Fifth Embodiment

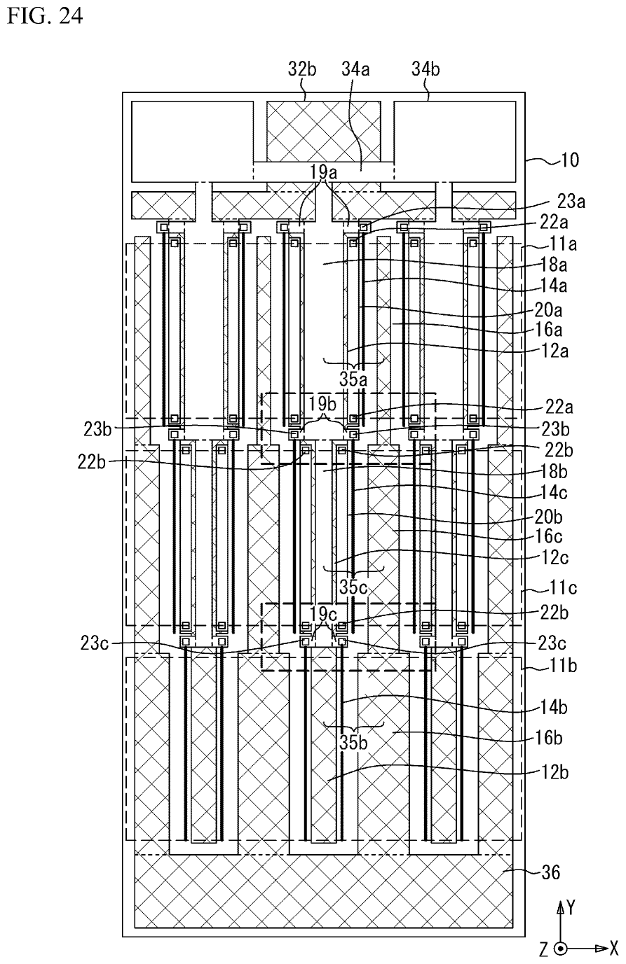

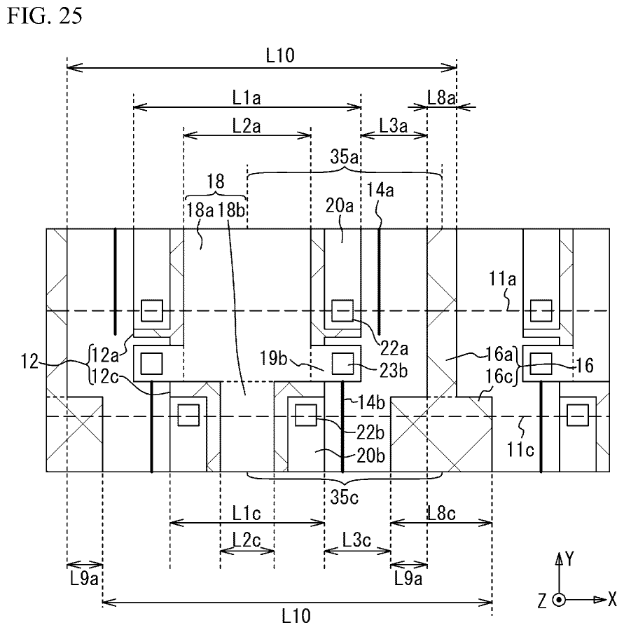

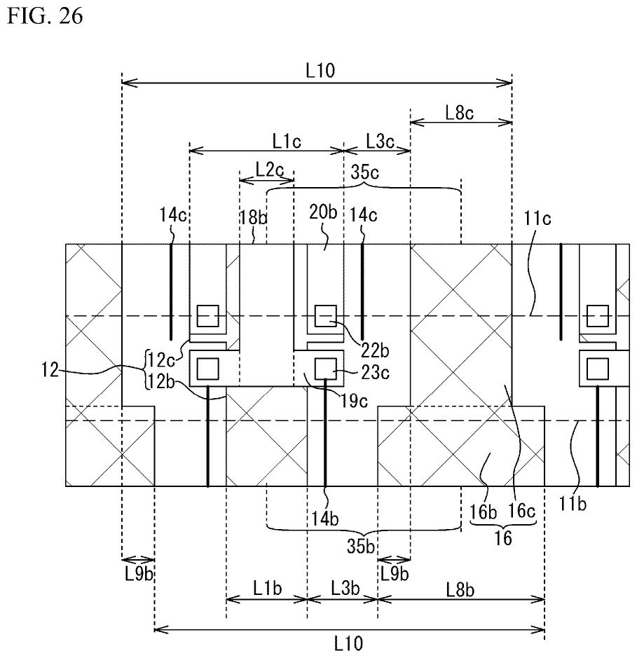

FIG. 24 is a plan view of a semiconductor device according to a first modification of the fifth embodiment. FIG. 25 is an enlarged plan view of a vicinity between the gate electrodes 14a and 14c in FIG. 24. FIG. 26 is an enlarged plan view of a vicinity between the gate electrodes 14c and 14b in FIG. 24.

As illustrated in FIGS. 24 to 26, the source electrode 12 includes source electrodes 12a, 12b and 12c, and the drain electrode 16 includes drain electrodes 16a, 16b and 16c. The source electrode 12a and the drain electrode 16a interpose the gate electrode 14a to form the unit FET 35a. The source electrode 12b and the drain electrode 16b interpose the gate electrode 14b to form the unit FET 35b. The source electrode 12c and the drain electrode 16c interpose the gate electrode 14c to form the unit FET 35c.

The lengths of the source electrodes 12a, 12b, and 12c in the X direction are L1a, L1b, and L1c, respectively. The lengths of the drain electrodes 16a, 16b and 16c are L8a, L8b and L8c in the X direction, respectively. The distance between the source electrode 12a and the drain electrode 16a in the X direction is L3a, the distance between the source electrode 12b and the drain electrode 16b in the X direction is L3b, and the distance between the source electrode 12c and the drain electrode 16c in the X direction is L3c. The distances L3a, L3b and L3c are approximately equal.

The gate wiring 18 includes gate wirings 18a and 18b extending in the Y direction. The gate wiring 18a is provided above the source electrode 12a and electrically connects the gate pad 34b and the gate electrode 14c. The gate wiring 18b is provided above the source electrode 12c and electrically connects the gate pad 34b and the gate electrode 14b. The other configurations are the same as those of the third embodiment, and the description thereof is omitted.

According to the first modification of the fifth embodiment, the length L1c of the source electrode 12c (third source electrode) in the X direction is smaller than the length L1a of the source electrode 12a (first source electrode) in the X direction and larger than the length L1b of the source electrode 12b (second source electrode) in the X direction. The length L8c of the drain electrode 16c (third drain electrode) in the X direction is larger than the length L8a of the drain electrode 16a (first drain electrode) in the X direction and smaller than the length L8b of the drain electrode 16b (second drain electrode) in the X direction. A difference between the length L1a of the source electrode 12a and the length L1c of the source electrode 12c is 2×L9a, and a difference between the length L8a of the drain electrode 16a and the length L8c of the drain electrode 16c is 2×L9a. A difference between the length L1c of the source electrode 12c and the length L1b of the source electrode 12b is 2×L9b, and a difference between the length L8c of the drain electrode 16c and the length L8b of the drain electrode 16b is 2×L9b.

The length L10 in the X direction of two unit FETs 35a (and 35b) is given by:

$$L 10 = L 1 a + 2 \times L 3 a + L 8 a = L 1 b + 2 \times L 3 b + L 8 b$$

$$and$$

$$L 10 = L 1 a + 2 \times L 3 a + L 8 b - 2 \times ( L 9 a + L 9 b )$$

Thus, also in the first modification of the fifth embodiment, the chip size of the semiconductor device can be reduced, and the semiconductor device can be miniaturized.

Assuming that the gate widths of the unit FETs 35a, 35b, and 35c in the Y direction are substantially the same, the current Isb is about one third of the current Isa, and the current Isc is about two-thirds of the current Isa. Therefore, when the length L1b is set to one third of the length L1a and the length L1c is set to two-thirds of the length L1a, the currents Isb and Isc are substantially the maximum current densities. Similarly, the current Ida is about one third of the current Idb, and the current Idc is about two-thirds of the current Idb. Therefore, when the length L8a is set to one third of the length L8b and the length L8c is set to two-thirds of the length L8b, the currents Ida and Idc are substantially the maximum current densities.

From the viewpoint that the currents Isb, Isc, Ida and Idc do not exceed the maximum current densities, the following relationship is established.

$$\begin{matrix}L 1 b \geq 1 / 3 \times L 1 a \geq 1 / 2 L 1 c \\ L 1 c > 2 / 3 \times L 1 a\end{matrix}$$

$$i . e .$$

$$\begin{matrix}L 9 a + L 9 b < 1 / 3 \times L 1 a \\ L 9 a < 1 / 6 \times L 1 a\end{matrix}$$

$$and$$

$$\begin{matrix}L 8 a > 1 / 3 \times L 8 b > 1 / 2 L 8 c \\ L 8 c \geq 2 / 3 \times L 8 b\end{matrix}$$

$$i . e .$$

$$\begin{matrix}L 9 a + L 9 b < 1 / 3 \times L 8 b \\ L 9 b < 1 / 6 \times L 8 b\end{matrix}$$

Thus, the length L1b is preferably 0.5 times or more, and more preferably 0.6 times or more the length L1c. The length L1c is preferably 0.67 times or more the length L1c, and more preferably 0.8 times or more the length L1a. The length L8d is preferably 0.5 times or more, and more preferably 0.6 times or more the length L8c. The length L8c is preferably 0.67 times or more, and more preferably 0.8 times or more the length L8b.

From the viewpoint of miniaturization of the semiconductor device, the length L1b is preferably 0.9 times or less, more preferably 0.8 times or less, and still more preferably 0.7 times or less the length L1c. The length L1c is preferably 0.95 times or less, more preferably 0.9 times or less, and still more preferably 0.8 times or less the length L1a. The length L8a is preferably 0.9 times or less, more preferably 0.8 times or less, and still more preferably 0.7 times or less the length L8c. The length L8c is preferably 0.95 times or less, more preferably 0.9 times or less, and still more preferably 0.8 times or less the length L8b.

The gate wiring 18a supplies a current to the gate electrodes 14b and 14c, while the gate wiring 18b supplies a current to the gate electrode 14b but does not supply a current to the gate electrode 14c. Therefore, the current Igb flowing through the gate wiring 18b is smaller than the current Iga flowing through the gate wiring 18a. Therefore, the length L2c of the gate wiring 18b (second gate wiring) in the X direction is made smaller than the length L2a of the gate wiring 18a (first gate wiring) in the X direction. This makes it possible to miniaturize the semiconductor device.

Assuming that the gate widths of the unit FETs 35b and 35c in the Y direction are substantially the same, the current Igb flowing through the gate wiring 18b is about ½ of the current Iga flowing through the gate wiring 18a. Therefore, when the length L2c is set to ½ of the length L2a, the current densities of the currents flowing through the gate wirings 18a and 18b are substantially the same. From the viewpoint that the current Igb does not exceed the maximum current density, the length L2c is preferably 0.5 times or more, and more preferably 0.6 times or more the length L2a. From the viewpoint of miniaturization of the semiconductor device, the length L2c is preferably 0.9 times or less, more preferably 0.8 times or less, and still more preferably 0.7 times or less the length L2a.

As described above, even if the length L1c of the source electrode 12c is made smaller than the length L1a of the source electrode 12a, the length L2c of the gate wiring 18b can be made smaller than the length L2a of the gate wiring 18a. Therefore, the lengths L5 of the guard metal layers 20a and 20b in the X direction can be substantially the same.

Although the source pad 32b connected to the source electrode 12a is described as an example in the fifth embodiment and the first modification, the source electrode 12a may be electrically connected to the metal layer 29 through the vias 28 as in the first and second modifications of the third embodiment.

In the first to fourth embodiments and the modification thereof, the lengths of the source electrodes 12 in the X direction may be different from each other, and the lengths of the drain electrodes 16 in the X direction may be different from each other, as in the fifth embodiment and the first modification thereof.

Although the first to fifth embodiments and the modifications thereof have been described with reference to the example in which six unit FETs 35a to 35c are arranged in the X direction, the number of unit FETs 35a to 35c in the X direction can be freely designed.

The embodiments disclosed herein should be considered in all respects exemplary and not restrictive. The scope of the present disclosure is not limited to the embodiment described above, is set forth by the claims and is intended to include all variations within the meaning and scope of equivalents of the claims.

### REFERENCE SIGNS LIST

10, 10a substrate
10b semiconductor layer
11a to 11c active region
12 source electrode
12a source electrode (first source electrode)
12b source electrode (second source electrode)
12c source electrode (third source electrode)
13 inactive region
14a gate electrode (first gate electrode)
14b gate electrode (second gate electrode)
14c gate electrode (third gate electrode)
15 gate connection wiring
15a pad
16 drain electrode
16a drain electrode (first drain electrode)
16b drain electrode (second drain electrode)
16c drain electrode (third drain electrode)
17 source wall
18, 19a, 19c gate wiring
18a gate wiring (first gate wiring)
18b gate wiring (second gate wiring)
19b gate wiring (gate connection wiring)
20a, 20b guard metal layer
22a, 22b, 23a to 23d via wiring
24, 24a, 24b insulating film
26 opening
28 via
32a source bus bar
32b source pad
34a gate wiring
34b gate pad
35a to 35c unit FET
36 drain pad
38 line of electric force
40, 42 connection wiring
52 input matching circuit
54 output matching circuit
55 FET

1. A semiconductor device comprising:
a substrate;
a source electrode that extends in a first direction and is provided on the substrate;
a drain electrode that extends in the first direction and is provided on the substrate;
a first gate electrode that extends in the first direction and is provided on the substrate between the source electrode and the drain electrode;
a second gate electrode that extends in the first direction and is provided on the substrate in the first direction of the first gate electrode between the source electrode and the drain electrode;
a gate pad that is provided so as to interpose the first gate electrode between the second gate electrode and the gate pad, and electrically connected to the first gate electrode;
a gate wiring that is provided above the source electrode on a side opposite to the substrate, extends in the first direction, and electrically connects the gate pad and the second gate electrode; and
a guard metal layer that is provided between the gate wiring and the drain electrode, extends in the first direction, at least a part of the guard metal layer being provided above the source electrode and electrically connected to the source electrode.

2. The semiconductor device according to claim 1, wherein an end of the guard metal layer close to the drain electrode in a second direction perpendicular to the first direction is located closer to the gate wiring than an end of the first gate electrode close to the source electrode in the second direction.

3. The semiconductor device according to claim 1, further comprising:
an insulating film provided between the source electrode, and the gate wiring and the guard metal layer in a normal direction of an upper surface of the substrate.

4. The semiconductor device according to claim 1, further comprising:
a gate connection wiring that is provided above the source electrode on a side opposite to the substrate, and extends in a second direction orthogonal to the first direction, a first end of the gate connection wiring being connected to the gate wiring, and a second end of the gate connection wiring on a side opposite to the first end being electrically connected to an end of the second gate electrode close to the first gate electrode outside the source electrode.

5. The semiconductor device according to claim 1, further comprising:
a gate connection wiring that is provided on the substrate, extends in a second direction perpendicular to the first direction, and electrically connects the gate wiring and the second gate electrode;
wherein the gate connection wiring intersects the source electrode between the substrate and the source electrode in a non-contact manner, and
the source electrode has an opening in a region intersecting the gate connection wiring when viewed from a normal direction of an upper surface of the substrate, and
the gate connection wiring intersects the source electrode in a non-contact manner below the source electrode and is electrically connected to the gate wiring through the opening.

6. The semiconductor device according to claim 1, further comprising:
a gate connection wiring that is provided on the substrate, extends in a second direction perpendicular to the first direction, and electrically connects the gate wiring and the second gate electrode;
wherein the source electrode is separated on the substrate into a first source electrode and a second source electrode, the first source electrode and the drain electrode interpose the first gate electrode, and the second source electrode and the drain electrode interpose the second gate electrode,
the guard metal layer electrically connects the first source electrode and the second source electrode, and
the gate connecting wiring intersects the guard metal layer in a non-contact manner below the guard metal layer.

7. The semiconductor device according to claim 5, wherein an end of the guard metal layer on a side opposite to the gate pad is located at a position coincident with an end of the gate wiring on a side opposite to the gate pad or at a position farther away from the end of the gate wiring on a side opposite to the gate pad toward a side opposite to the gate pad.

8. The semiconductor device according to claim 1, wherein
the first gate electrode and the second gate electrode are separated from each other in the first direction on an upper surface of the substrate.

9. The semiconductor device according to claim 1, wherein
in a normal direction of an upper surface of the substrate, a thickness of each of the source electrode and the drain electrode is larger than a thickness of each of the first gate electrode and the second gate electrode.

10. The semiconductor device according to claim 1, further comprising:
a third gate electrode that extends in the first direction between the source electrode and the drain electrode and is provided on the substrate between the first gate electrode and the second gate electrode;
wherein the gate wiring electrically connects the gate pad and the third gate electrode.

11. The semiconductor device according to claim 1, wherein
a plurality of source electrodes, a plurality of drain electrodes, a plurality of first gate electrodes, a plurality of second gate electrodes, a plurality of gate wirings, and a plurality of guard metal layers are provided in a direction in which the source electrodes and the drain electrodes are arranged, and
the semiconductor device includes a connection wiring that electrically connects adjacent guard metal layers provided with one of the drain electrodes interposed therebetween and intersects the drain electrodes in a non-contact manner above the drain electrodes.

12. The semiconductor device according to claim 1, further comprising:
a drain pad provided on the substrate;
wherein the source electrode includes a first source electrode and a second source electrode, the first source electrode and the drain electrode interpose the first gate electrode, and the second source electrode and the drain electrode interpose the second gate electrode,
the drain electrode includes a first drain electrode and a second drain electrode, the first drain electrode and the second source electrode interpose the first gate electrode, and the second drain electrode and the second source electrode interpose the second gate electrode,
the drain pad is provided so as to interpose the second drain electrode between the drain pad and the first drain electrode, and is electrically connected to the second drain electrode,
a length of the first source electrode in a second direction orthogonal to the first direction is larger than a length of the second source electrode in the second direction, and
a length of the first drain electrode in the second direction is smaller than a length of the second drain electrode in the second direction.

13. The semiconductor device according to claim 1, further comprising:
a third gate electrode that extends in the first direction between the source electrode and the drain electrode and is provided on the substrate between the first gate electrode and the second gate electrode; and
a drain pad provided on the substrate;
wherein the gate wiring electrically connects the gate pad and the third gate electrode,
the source electrode includes a first source electrode, a second source electrode and a third source electrode, the first source electrode and the drain electrode interpose the first gate electrode, the second source electrode and the drain electrode interpose the second gate electrode, and the third source electrode and the drain electrode interpose the third gate electrode,
the drain electrode includes a first drain electrode, a second drain electrode, and a third drain electrode, the first drain electrode and the first source electrode interpose the first gate electrode, the second drain electrode and the second source electrode interpose the second gate electrode, and the third drain electrode and the third source electrode interpose the third gate electrode,
the drain pad is provided so as to interpose the second drain electrode between the third drain electrode and the drain pad, and is electrically connected to the second drain electrode,
a length of the third source electrode in a second direction orthogonal to the first direction is smaller than a length of the first source electrode in the second direction and larger than a length of the second source electrode in the second direction, and
a length of the third drain electrode in the second direction is larger than a length of the first drain electrode in the second direction and smaller than a length of the second drain electrode in the second direction.

14. The semiconductor device according to claim 13, wherein
the gate wiring includes a first gate wiring that is provided above the first source electrode and electrically connects the gate pad and the third gate electrode, and a second gate wiring that is provided on the third source electrode and electrically connects the gate pad and the second gate electrode, and
a length of the first gate wiring in the second direction is larger than a length of the second gate wiring in the second direction.
